(19) United States
(12) Patent Application Publication
(10) Pub. No.: US 2007/0252217 A1
(43) Pub. Date: Nov. 1, 2007

(54) SEMICONDUCTOR DEVICE

(75) Inventor: Yasumitsu OKI, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 11/738,958

(22) Filed: Apr. 23, 2007

(30) Foreign Application Priority Data
Apr. 28, 2006 (JP) 2006-125377

(51) Int. Cl. H01L 29/94; H01L 29/76; H01L 31/00

(52) U.S. Cl. 257/369

(57) ABSTRACT

A semiconductor device comprises a decoupling capacitance in which a P-type MOS capacitor C1 is connected in series with an N-type MOS capacitor C2 between VDD and GND. The source and drain 2b of the P-type MOS capacitor C1 are connected to VDD. The source and drain 2a of the N-type MOS capacitor C2 are connected to GND. The gate electrode 5a of the P-type MOS capacitor C1 is connected to the gate electrode 5b of the N-type MOS capacitor C2. VDD is connected to the N-well region 1b of the channel of the P-type MOS capacitor C1, and GND is connected to the P-well region 1a of the channel of the N-type MOS capacitor C2. Reliability of decoupling capacitance is improved, making it possible to place elements efficiently.

### FIELD OF THE INVENTION

This invention relates to a semiconductor device that has a decoupling capacitance, and more particularly to a semiconductor device that can improve the reliability of the capacitance.

In this semiconductor device, in order to shut out undesirable signals and noise that are transmitted by wiring in an electric circuit, a decoupling capacitance is placed near the electric circuit. The decoupling capacitance is placed between a VDD wiring that is electrically connected to the power supply (VDD) and a ground (GND) wiring that is electrically connected to GND. Normally, a MOS capacitor that is capable of obtaining large capacitance with small surface area is used as a decoupling capacitance.

A semiconductor device has been disclosed as a conventional example of using a MOS capacitor as a decoupling capacitance, and is a decoupling capacitance that comprises a first and second MOS capacitor 109, 110 that are connected in series between an internal power supply and GND, where a voltage that is approximately ½ the voltage between the internal power supply Vpp 106 and GND 107 is applied to the first and second MOS capacitors 109, 110, respectively and reliability is improved by connecting the MOS capacitors in series (see FIG. 10 and patent document 1).

[Patent Document 1] Japanese Patent Kokai Publication JP-A-10-256489

### SUMMARY OF THE DISCLOSURE

In the following analyses are given by the present invention. The entire disclosure of the above patent document is herein incorporated by reference thereto.

However, when a decoupling capacitance is constructed using a single element (MOS capacitor) as in the related art, there are problems in that as the process becomes more miniaturized, the gate insulation film becomes thinner and current leakage increases.

Also, in patent document 1, the P well region 101 that forms respective channels for the first and second MOS capacitors 109, 110 is common. When this kind of construction is applied to a CMOS, it is only possible to place the first and second MOS capacitors 109, 110 on only the P well region 101 or N well region 118, so there is a possibility that the area efficiency of the element region will become poor, and that there will be a drop in freedom of design. For example, in the case where the ratio of the N well region and the P well region in the element region is 5:4, then when the first and second MOS capacitors 109, 110 are placed on the P well region 101 as disclosed in patent document 1, it is only possible to place the first and second MOS capacitors 109, 110 on 5/9 of the entire area (see FIG. 11).

Taking this problem into consideration, it is an object of the present invention to provide a semiconductor device that improves reliability of the decoupling capacitance, and in which efficient element placement is possible.

In a first aspect of the present invention, there is provided a semiconductor device comprising a decoupling capacitance cell in which a P-type MOS capacitor and N-type MOS capacitor are connected in series between a power supply and ground.

It is preferred that either a source or drain or both of the P-type MOS capacitor be connected to the power supply, that either a source or drain or both of the N-type MOS capacitor be connected to ground, and that a gate electrode of the P-type MOS capacitor be connected to a gate electrode of the N-type MOS capacitor. It is also preferred that the power supply be connected to a N-well region of a channel of the P-type MOS capacitor, and that ground be connected to a P-well region of a channel of the N-type MOS capacitor.

It is preferred that the gate electrode of the P-type MOS capacitor is integrated with the gate electrode of the N-type MOS capacitor.

It is preferred that the P-type MOS capacitor and the N-type MOS capacitor are adjacent; and there is an element isolation region between the P-type MOS capacitor and the N-type MOS capacitor.

It is preferred that the decoupling capacitance is placed as a decoupling capacitance cell between standard cells in an element region.

It is preferred that the decoupling capacitance has a longer gate length than that of the standard cells.

It is preferred that power supply wiring for the power supply is placed on a N-well region, and ground wiring for the ground is placed on a P-well region.

The meritorious effects of the present invention are summarized as follows.

With the present invention it is possible to improve reliability more than with a decoupling capacitance having only one MOS capacitor. Also, in a semiconductor having the CMOS structure, it is possible to efficiently utilize cell size in a layout.

### BRIEF DESCRIPTIONS OF THE DRAWINGS

FIG. 1A to FIG. 1C are drawings showing the construction of the semiconductor device of a first example of the invention, where FIG. 1A is a partial cross sectional view of section A-A′ of FIG. 2, FIG. 1B is a circuit diagram, and FIG. 1C is an equivalent circuit diagram.

FIG. 2 is a partial top plan view of the construction of the semiconductor device of a first example of the invention.

FIG. 3 is a graph that shows the relationship between the voltage and defective rate in order to explain a decoupling capacitance cell of the semiconductor device of a first example of the invention.

FIG. 4 is a partial top plan view showing the construction of a variation of the semiconductor device of a first example of the invention.

FIG. 5 is a partial top plan view showing an example of the combination of semiconductor device cells of a second example of the invention.

FIG. 6 is a partial top plan view showing the construction of part of the area (area indicated by arrow B in FIG. 5) of the semiconductor device of a second example of the invention.

FIG. 7 is a partial cross sectional view of the section C-C′ in FIG. 6, and shows the construction of the semiconductor device of a second example of the invention.

FIG. 8 is a partial cross sectional view of the section D-D′ in FIG. 6, and shows the construction of the semiconductor device of a second example of the invention.

FIG. 9 is an equivalent circuit diagram that shows the construction of the inverter circuit inside the area shown in FIG. 6 of the semiconductor device of a second example of the invention.

FIG. 10A and FIG. 10B are drawings showing the construction of a conventional semiconductor device, where FIG. 1A is a partial cross sectional view, and FIG. 10B is an equivalent circuit diagram.

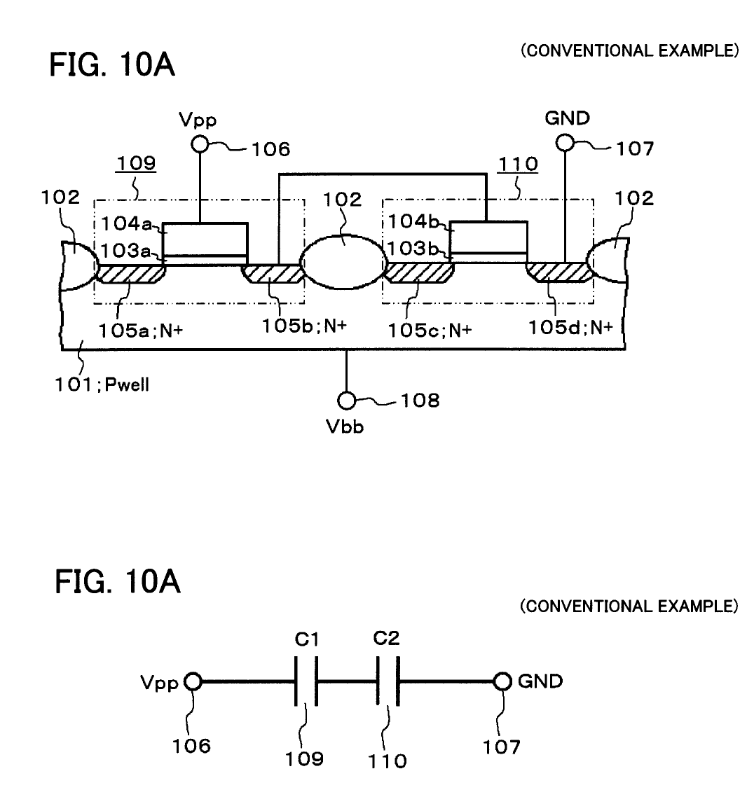

FIG. 11 is a partial top plan view showing the construction of a semiconductor device of a comparative example in which a conventional semiconductor device is applied to CMOS construction.

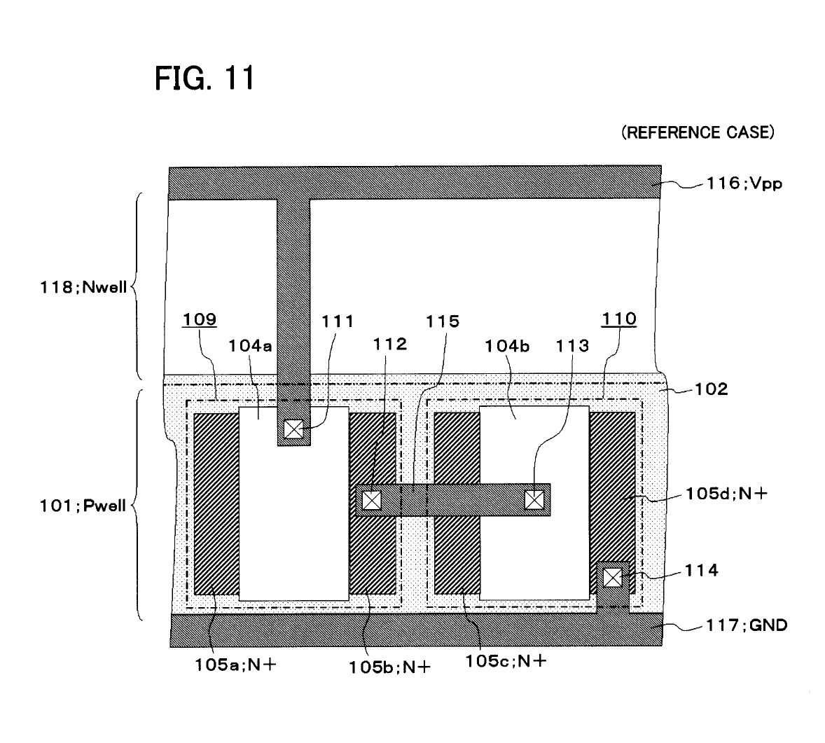

### PREFERRED MODES OF THE INVENTION

### Example 1

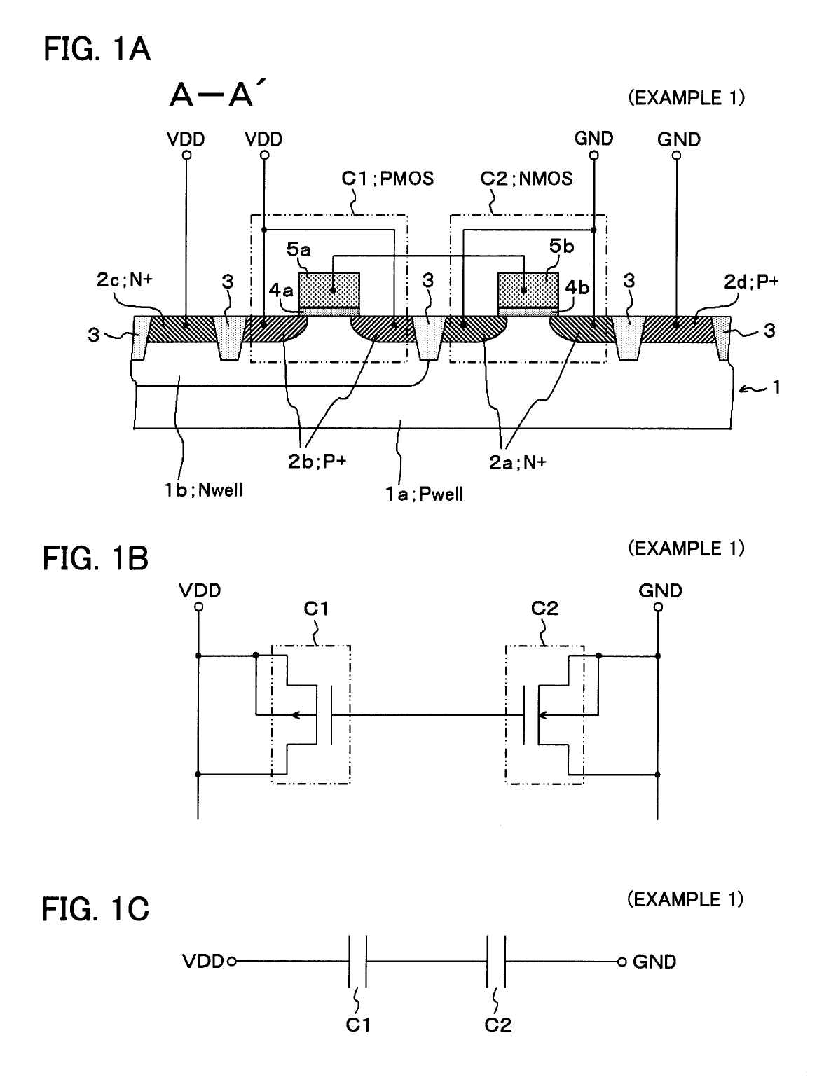

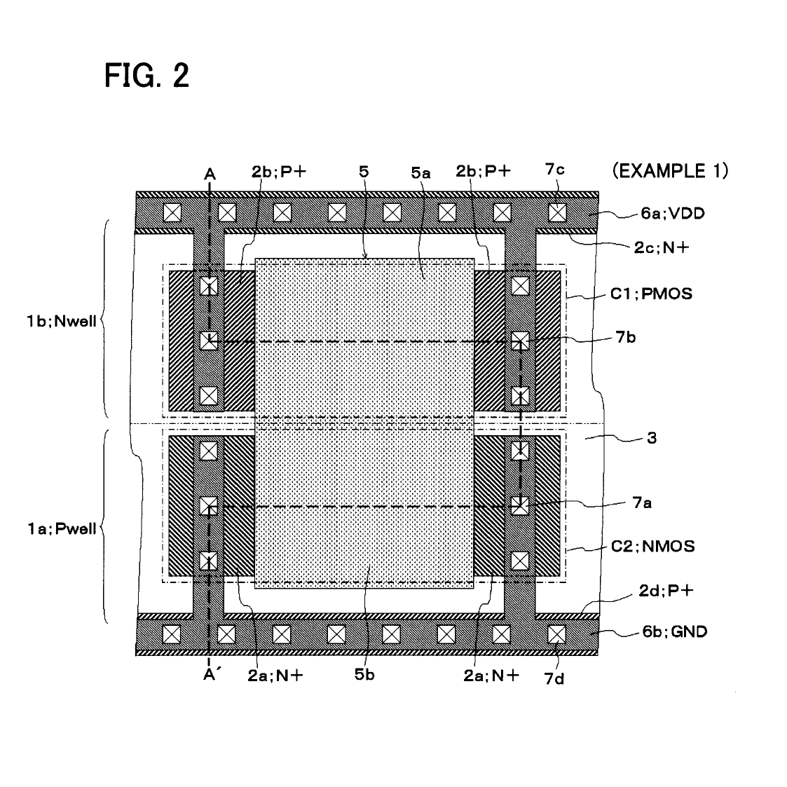

The semiconductor device of a first example of the present invention will be explained using the drawings. FIG. 1A to FIG. 1C are drawings showing the construction of the semiconductor device of a first example of the invention, where FIG. 1A is a partial cross sectional view of section A-A′ of FIG. 2, FIG. 1B is a circuit diagram, and FIG. 1C is an equivalent circuit diagram. FIG. 2 is a partial cross sectional view of the construction of the semiconductor device of a first example of the invention. In FIG. 1A, in order to better understand the wiring structure, the wiring and vias are omitted.

This semiconductor device is a CMOS device that simultaneously has N-type MOS structure and P-type MOS structure, and has a decoupling capacitance comprising a P-type MOS capacitor C1 and N-type MOS capacitor C2 that are connected in series between the power supply (VDD) and GND. The structural components of the semiconductor device include a substrate 1, high-density diffusion regions 2, element isolation region 3, gate insulation films 4, gate electrodes 5, wiring 6, and vias 7.

The substrate 1 is a semiconductor substrate (silicon substrate) and comprises a P-well region 1a and N-well region 1b. The P-well region 1a is a well in which a P-type impurity such as boron B is introduced into silicon by diffusion or implantation, and functions as a channel for the N-type MOS capacitor C2. The P-well region 1a is electrically connected to the GND wire by way of the P+ diffusion region 2d and via 7d, and has the same potential as the GND wire. A N-well region 1b is a well in which an N-type impurity such as phosphorus P is introduced into silicon by diffusion or implantation, and functions as a channel for the P-type MOS capacitor C1. The N-well region 1b is electrically connected to the VDD wiring 6a by way of an N+ diffusion region 2c and via 7c, and has the same potential as the VDD wiring 6a. It is also possible to use a P-type silicon substrate as is as the P-well region 1a, and it is possible to use a P-type silicon substrate in which an N-type impurity has been implanted as the N-well region 1b. In the explanation below, since an explanation of introducing impurities by diffusion or implantation is complicated, it will simply be stated that the substrate is diffused with impurities.

The high-density diffusion regions 2 are regions in which a high-density of impurities are diffused into the P-well region 1a and N-well region 1b, and comprises N+ diffusion regions 2a, P+ diffusion regions 2b, N+ diffusion region 2c and P+ diffusion region 2d.

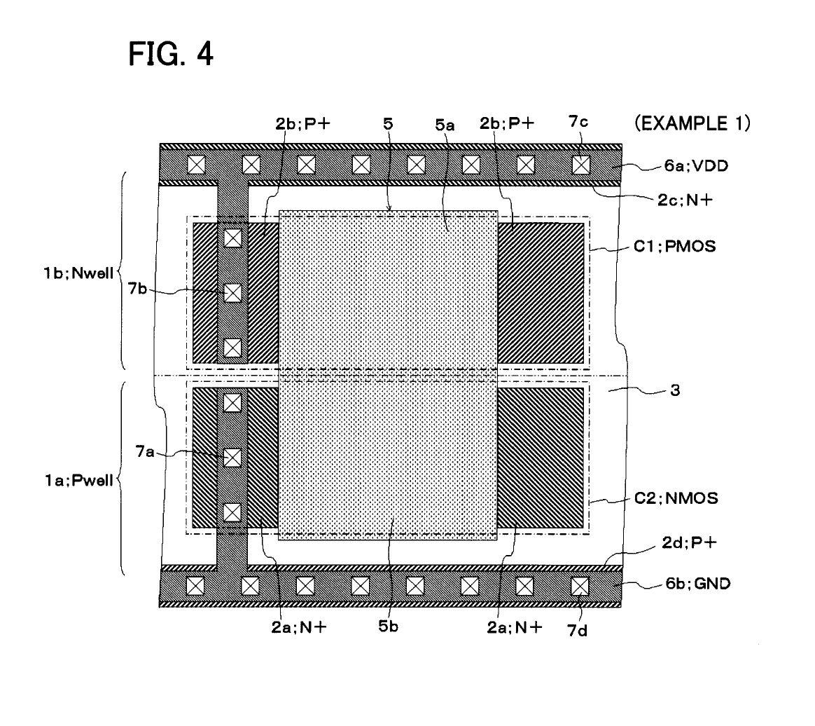

The N+ diffusion regions 2a are impurity diffusion regions in the P-well region 1a in which an N-type impurity is diffused that has conductivity that is reverse to that of the P-well region 1a, and in which the impurity has a higher density than that of the N-well region 1b. The N+ diffusion regions 2a are located so that they are separated in the regions on both sides of the gate electrode 5b, and they become source/drain regions of the N-type MOS capacitor C2. The N+ diffusion regions 2a are electrically connected to the GND wiring 6b by way of the via 7a, and have the same potential as the GND wiring 6b. In FIG. 1A and FIG. 2, both of the separated N+ diffusion regions 2a are electrically connected to the GND wiring 6b by way of the via 7a, however, it is also possible for only one to be electrically connected to the GND wiring 6b by way of the via 7a (see FIG. 4). In FIG. 4, only the N+ diffusion region 2a on the left side is electrically connected to the GND wiring 6b by way of the via 7a, however, it is also possible for only the N+ diffusion region 2a on the right side to be electrically connected to the GND wiring 6b by way of the via 7a. The N+ diffusion regions 2a are isolated from the P+ diffusion regions 2b and P+ diffusion region 2d, respectively, by an element isolation region 3.

The P+ diffusion regions 2b are impurity diffusion regions in the N-well region 1b in which a P-type impurity is diffused that has conductivity that is reverse to that of the N-well region 1b, and in which the impurity has a higher density than that of the P-well region 1a. The P+ diffusion regions 2b are located so that they are separated in the regions on both sides of the gate electrode 5a, and they become source/drain regions of the P-type MOS capacitor C1. The P+ diffusion regions 2b are electrically connected to the VDD wiring 6a by way of the via 7b, and have the same potential as the VDD wiring 6a. In FIG. 1A and FIG. 2, both of the separated P+ diffusion regions 2b are electrically connected to the VDD wiring 6a by way of the via 7b, however, it is also possible for only one to be electrically connected to the VDD wiring 6a by way of the via 7b (see FIG. 4). In FIG. 4, only the P+ diffusion region 2a on the left side is electrically connected to the VDD wiring 6a by way of the via 7b, however, it is also possible for only the P+ diffusion region 2b on the right side to be electrically connected to the VDD wiring 6a by way of the via 7b. The P+ diffusion regions 2b are isolated from the N+ diffusion regions 2a and N+ diffusion region 2c, respectively, by the element isolation region 3.

The N+ diffusion region 2c is an impurity diffusion region in the N-well region 1b in which a high density of P-type impurity is diffused that has the same conductivity as that of the N-well region 1b, and is electrically connected to the VDD wiring 6a by way of the via 7c so that its potential is the same as the VDD wiring 6a. The N+ diffusion area 2c is isolated from the P+ diffusion regions 2b by the element isolation region 3.

The P+ diffusion region 2d is an impurity diffusion region in the P-well region 1a in which a high density of N-type impurity is diffused that has the same conductivity as that of the P-well region 1a, and is electrically connected to the GND wiring 6b by way of the via 7d so that its potential is the same as the GND wiring 6b. The P+ diffusion area 2d is isolated from the N+ diffusion regions 2a by the element isolation region 3.

The element isolation region 3 is a region that electrically separates the elements by an insulating material (for example, silicon oxide film), and the structure such as LOCOS (Local Oxidation of Silicon) or STI (Shallow Trench Isolation) can be used. The element isolation region 3 provides isolation between the N+ diffusion regions 2a and P+ diffusion regions 2b, between the N+ diffusion regions 2a and the P+ diffusion region 2d, and between the P+ diffusion regions 2b and the N+ diffusion region 2c.

A gate insulation film 4 is made, for example, from silicon oxide film, or silicon oxynitride film. The gate insulation film 4a is located between the gate electrode 5a of the P-type MOS capacitor C1 and the N-well region 1b. The gate insulation film 4b is located between the gate electrode 5b of the N-type MOS capacitor C2 and the P-well region 1a.

Gate electrodes 5 are made, for example, from a material such as polysilicon or metal. The gate electrode 5a of the P-type MOS capacitor C1 is located on the gate insulation film 4a of the P-type MOS capacitor C1. The gate electrode 5b of the N-type MOS capacitor C2 is located on the gate insulation film 4b of the N-type MOS capacitor C2. In FIG. 2 the construction of the gate electrode 5a of the P-type MOS capacitor C1 and the gate electrode 5b of the N-type MOS capacitor C2 is such that they are integrated together, however, depending on the design, they can be separated and electrically connected by a via (not shown in the figures) or wiring (not shown in the figures). Also, in FIG. 2, gate electrode 5a and gate electrode 5b are integrated together into an I shape, however, depending on the design, they could also be integrated together to form a U shape.

The wiring 6 is wiring made from a conductive material (for example, metal) that is located on insulation film (not shown in the figure) of the substrate 1 (high-density diffusion regions 2, element isolation region 3, gate electrodes 5), and comprises VDD wiring 6a and GND wiring 6b. The VDD wiring 6a is wiring to which a VDD potential is applied, and is located on the N-well region 1b. The VDD wiring 6a is electrically connected to the P+ diffusion regions 2b by way of the via 7b, and is electrically connected to the N+ diffusion region 2c by way of the via 7c. The GND wiring 6b is wiring that electrically connects to GND, and is located on the P-well region 1a. When the VDD wiring 6a is electrically connected to only one of the two P+ diffusion regions 2b by way of the via 7b, branch wiring can be formed on the other P+ diffusion region 2b (see FIG. 4). The GND wiring 6b is electrically connected to the N+ diffusion regions 2a by way of the via 7a, and is electrically connected to the P+ diffusion region 2d by way of the via 7d. When the GND wiring 6b is electrically connected to only one of the two N+ diffusion regions 2a by way of the via 7a, branch wiring can be formed on the other N+ diffusion region 2a.

The vias 7 are made of an conductive material (for example metal, etc.), and are electrically connected to the wiring 6 and high-density diffusion regions 2, and are formed in holes (not shown in the figure) formed in an insulation film (not shown in the figure) on the substrate (high-density diffusion regions 2, element isolation region 3, gate electrodes 5), and they comprise via 7a, via 7b, via 7c and via 7d. Via 7a is electrically connected to the N+ diffusion regions 2a and to the GND wiring 6b. Via 7b is electrically connected to the P+ diffusion regions 2b and to the VDD wiring 6a. Via 7c is electrically connected to the N+ diffusion region 2c and to the VDD wiring 6a. Via 7d is electrically connected to the P+ diffusion region 2d and to the ground wiring 6b.

In regards to the wiring 6 and vias 7, the wiring layers and insulation layers can be alternately layered so that there are multiple layers with vias connected between the wiring layers. Also, in FIG. 2 construction is such that the P-type MOS capacitor C1 and N-type MOS capacitor C2 are adjacent, however, depending on the design, that can be separated.

With this first example, it is possible to reduce the effect of noise when there is noise in the VDD, which causes abnormal voltage to occur. Also, by maintaining a large capacitance, it is possible to keep a normal voltage across VDD and GND constant even though a drop in VDD occurs due to power consumption.

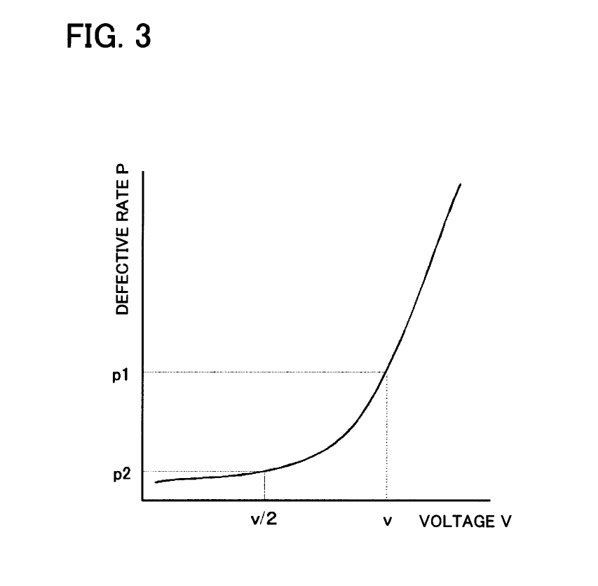

Also, it is possible to improve reliability when compared with a decoupling capacitance that comprises only one MOS capacitor. The reason for that is explained below. As shown in FIG. 3, the relationship between the voltage V applied to the decoupling capacitance and the defective rate P due to that voltage V has a relationship in which as the voltage V increases, the defective rate P increases exponentially. When the decoupling capacitance formed by connecting two MOS capacitors in series, for example, when the surface areas of the gates are such that the capacitance of the two MOS capacitors is the same, only ½ of the applied voltage v (v/2) is applied to each MOS capacitor, so when compared with the defective rate p1 in the case of a conventional decoupling capacitance in which the entire applied voltage v is applied to one MOS capacitor, the defective rate p2 becomes a lower value. Also, in the case of a decoupling capacitance that comprises two MOS capacitors that are connected in series, even when one of the MOS capacitors becomes damaged, the entire applied voltage v is applied to the remaining MOS capacitor instead of ½ the applied voltage v, resulting in a defective rate p1. In that case, the defective rate of the entire decoupling capacitance cell in which two MOS capacitors are connected in series is p2×p1, and becomes a value that is lower than the square of p1.

Furthermore, in a semiconductor device having the CMOS construction, it is possible to effectively utilize the cell size in the layout. The reason for this is that in a semiconductor device having the CMOS construction, there is typically P-well regions and N-well regions, and both an N-type MOS capacitor and P-type MOS capacitor can be mounted as the capacitance.

### Example 2

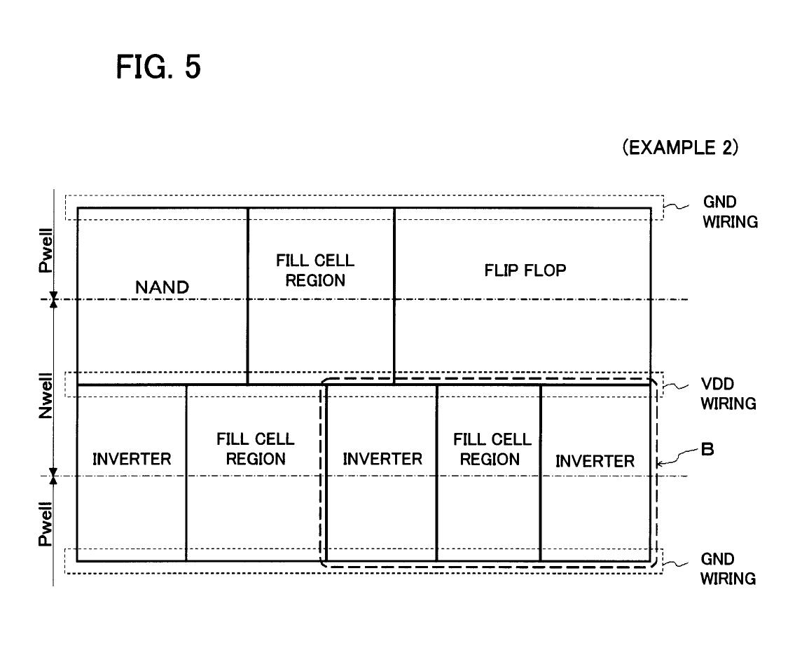

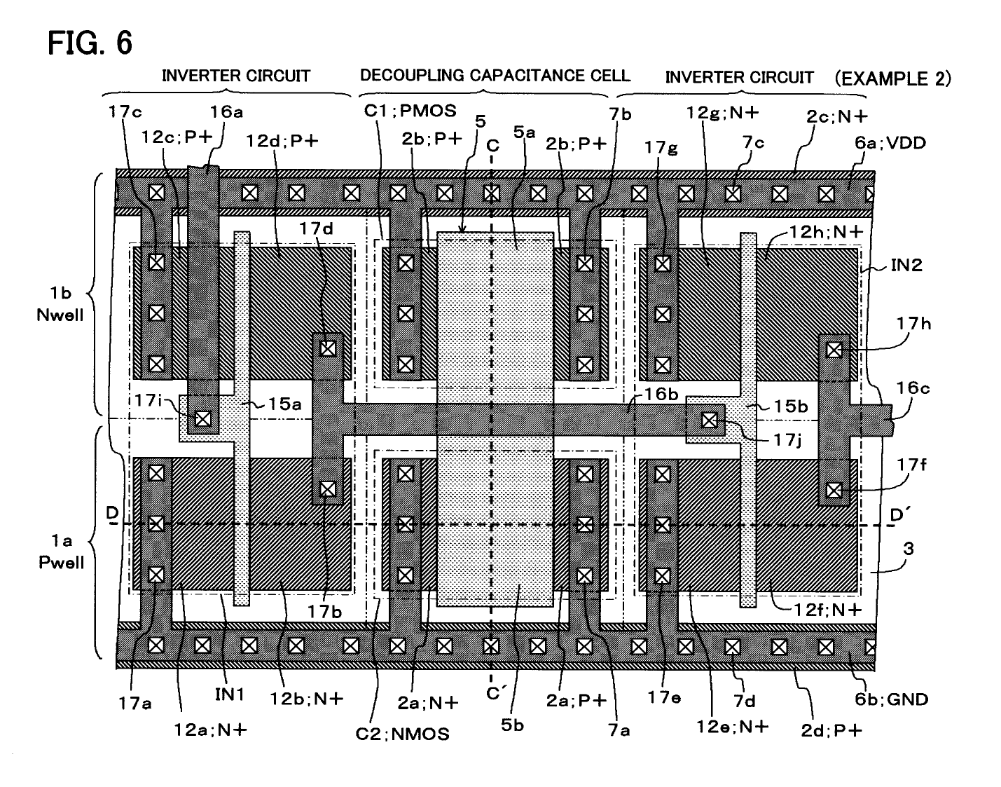

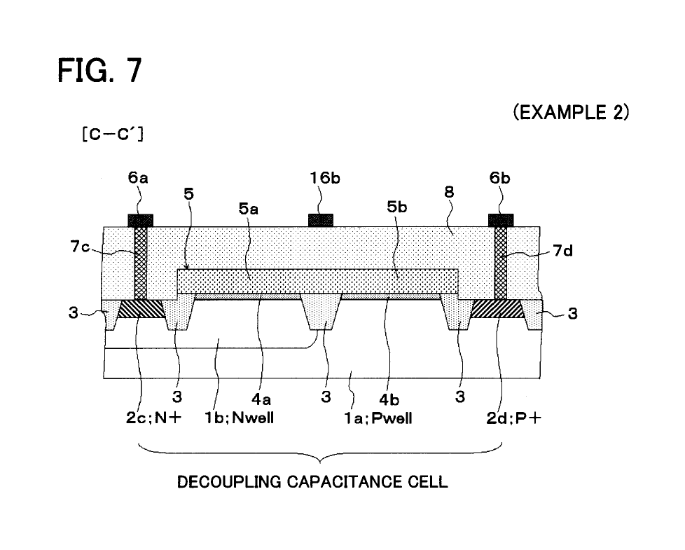

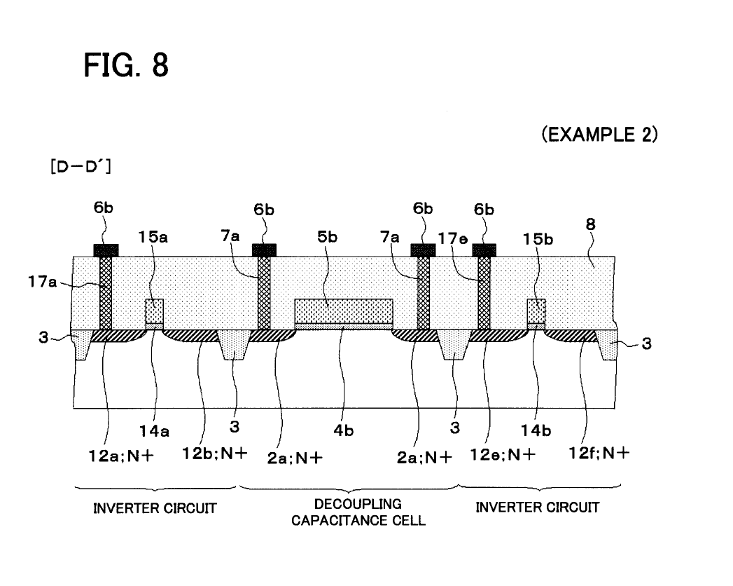

A semiconductor device of a second example of the invention will be explained using the drawings. FIG. 5 is a partial top plan view of an example of combining cells of the semiconductor device of this second example. FIG. 6 is a partial top plan view showing the construction of part of the area (area indicated by arrow B in FIG. 5) of the semiconductor device of this second example of the invention. FIG. 7 is a partial cross sectional view taken along the section C-C′ in FIG. 6, and shows the construction of the semiconductor device of this second example of the invention. FIG. 8 is a partial cross sectional view of the section D-D′ in FIG. 6, and shows the construction of the semiconductor device of this second example of the invention. The cell is a functional unit (functional block) of circuits or elements in the semiconductor device, and the same meaning is used in this specification.

For example, in the case of a semiconductor device such as a system LSI having a functional block that includes a macro, I/O cell, standard cells and the like, in auto layout of the design stage, placement of the standard cells in the element region has priority. Therefore, the order of priority for the placement of fill cells that include the decoupling capacitance cell, in which the decoupling capacitance is the functional unit, is low. The decoupling capacitance cell is placed between standard cells after the standard cells have been put in place in the course of layout designing.

Also, in auto layout, the minimum unit width (grid) is defined. The standard cell width and fill cell width are set as a multiple by integer of the grid width, and are not set to an arbitrary width. For example, fill cell widths that are 1×, 4×, 8×, 16×, etc. that of the grid are prepared, and of the fill cells, 1× the grid is too narrow for the width of a decoupling capacitance cell, so decoupling capacitance cell widths of 4×, 8×, 16× etc. have been prepared.

Here, “standard cells” denote basic cells such as an inverter circuit, NAND circuit, flip-flop circuit and the like that cannot be broken down any further, and are also called “function cells”. “Fill cells” denote cells that are placed at intermediary between cells after the standard cells and spare cells have been put in place. A “spare cell” denotes an extra function cell (extra cell) for making it easy to perform mask revision of just wiring. Cells that are not standard cells are called extra cells. Extra cells include fill cells and spare cells.

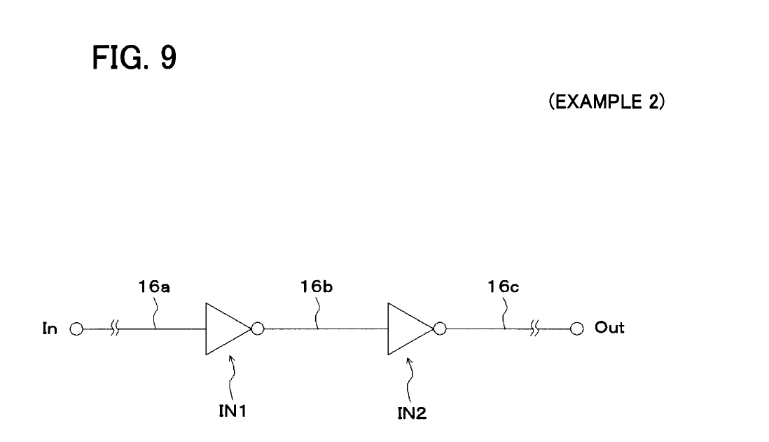

The procedure for executing auto-layout in an element region is as follows (see FIG. 5 and FIG. 6). First, the VDD wiring 6a and GND wiring 6b are put in place (i.e., laid-out). Here, just the common wirings (wiring without branch lines) of the VDD wiring 6a and GND wiring 6b are put in place. Next, standard cells such as inverter circuits, NAND circuits, flip-flop circuits and the like are put in place. An example, as shown in FIG. 9, is explained below in which a circuit that is constructed having an inverter circuit IN1 and inverter circuit IN2 connected in series between the input terminal IN and output terminal OUT is placed inside a broken-lined region B in FIG. 5. In the inverter circuit shown in FIG. 6, an N+ diffusion region 2c, P+ diffusion regions 2d, 12a to 12h and gate electrodes 15a, 15b are put in place. Next, spare cells (not shown in the figure) other than the fill cells are put in place. Next, the decoupling capacitance cell etc., is placed in the fill cell region. For example, a decoupling capacitance cell comprising N+ diffusion regions 2a, P+ diffusion regions 2b and gate electrodes 5 is placed, as shown in FIG. 6 in the fill cell region shown in FIG. 5. After that, auto-wiring is performed to put wiring other than the common wiring of the VDD wiring 6a and GND wiring 6b and the vias into place. For example, in FIG. 6, the branch lines of the VDD wiring 6a and GND wiring 6b, metal wiring 16a to 16c, and vias 7a to 7d, 17a to 17j are put in place.

Here, the construction of the decoupling capacitance shown in FIG. 6 is the same as the construction of the decoupling capacitance of the semiconductor device of the first example (see FIGS. 1, 2) described above (see FIGS. 7, 8). For a detailed explanation refer to the explanation of the first example.

Also, the construction of the inverter circuit in the region shown in FIG. 6 is as shown in FIG. 9 where an inverter circuit IN1 and inverter circuit IN2 are connected in series between an input terminal IN and output terminal OUT, and will be described in detail below.

In the inverter circuit IN1 on the left side of FIG. 6, there is laid-out an N-type MOS transistor in which a gate electrode 15a is placed on the channel in the P-well region 1a by way of a gate insulation film 14a, and N+ diffusion regions 12a, 12b that are the source and drain are placed on both sides of the gate electrode 15a (see FIG. 8). Also, in the inverter circuit IN1, there is a P-type MOS transistor in which a gate electrode 15a is placed on the channel in the N-well region 1b by way of a gate insulation film 14a, and P+ diffusion regions 12c, 12d that are the source and drain are placed on both sides of the gate electrode 15a. Here, the gate electrode 15a of the N-type MOS transistor and P-type MOS transistor is common, and the gate electrode 15a is electrically connected by way of via 17i to the metal wiring 16a that electrically connects to any other circuits. The metal wiring 16a crosses over the VDD wiring 6a without interfering with it. The N+ diffusion region 12a is electrically connected to the GND wiring 6b by way of via 17a. The N+ diffusion region 12b is electrically connected to the metal wiring 16b by way of via 17b. The P+ diffusion region 12c is electrically connected to the VDD wiring 6a by way of via 17c. The P+ diffusion region 12d is electrically connected to the metal wiring 16b by way of via 17d. The other circuits referred to here include various circuits such as standard cell circuits like inverter circuits and NAND circuits, circuits that connect to external terminals, etc.

In the inverter circuit IN2 on the right side of FIG. 6, there is an N-type MOS transistor in which a gate electrode 15b is placed on the channel in the P-well region 1a by way of a gate insulation film 14b, and N+ diffusion regions 12e, 12f that are the source and drain are placed on both sides of the gate electrode 15b (see FIG. 8). Also, in the inverter circuit IN2, there is a P-type MOS transistor in which a gate electrode 15b is placed on the channel in the N-well region 1b by way of a gate insulation film 14b, and P+ diffusion regions 12g, 12h that are the source and drain are placed on both sides of the gate electrode 15b. Here, the gate electrode 15b of the N-type MOS transistor and P-type MOS transistor is common, and the gate electrode 15b is electrically connected by way of via 17j to the metal wiring 16b that electrically connects to the inverter circuit (N+ diffusion region 12b, P+ diffusion region 12d) on the right side of FIG. 6. The metal wiring 16b crosses over the gate electrodes 5 of the fill cell without interfering. The N+ diffusion region 12e is electrically connected to the GND wiring 6b by way of via 17e. The N+ diffusion region 12f is electrically connected to the metal wiring 16c by way of via 17f. The P+ diffusion region 12g is electrically connected to the VDD wiring 6a by way of via 17g. The P+ diffusion region 12h is electrically connected to the metal wiring 16c by way of via 17h.

The gate length of the gate electrodes 5 (5a, 5b) of the decoupling capacitance cell is set so that it is longer than the gate length of the gate electrodes (for example, gate electrodes 15a, 15b) of the standard cells. For example, in FIG. 6, it can be clearly seen that the lengths of gate electrodes 5a and 15a are such that the length of gate electrode 5a, even when seen from the direction of section D-D′ of the figure, is thicker and longer than the length of the gate electrode 15a of the inverter circuit. The reason for this is to maintain capacitance. The shape of the MOS capacitors of the decoupling capacitance cell is clearly different from the shape of normal MOS transistors for switching.

With this second example, the same effects as the in the first example are obtained. FIG. 5 shows an example in which decoupling capacitance cell is placed in the fill cell region, however, of course it is also possible to place a cell other than the decoupling capacitance cell in the fill cell region, however, doing so is not related to the present invention, so an explanation of that case is omitted here.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising a decoupling capacitance in which a P-type MOS capacitor and N-type MOS capacitor are connected in series between a power supply and ground.

2. The semiconductor device of claim 1, wherein
either a source or drain or both of said P-type MOS capacitor is connected to said power supply;
either a source or drain or both of said N-type MOS capacitor is connected to said ground: and
a gate electrode of said P-type MOS capacitor is connected to a gate electrode of said N-type MOS capacitor.

3. The semiconductor device of claim 2, wherein
said power supply is connected to a N-well region of a channel of said P-type MOS capacitor; and
said ground is connected to a P-well region of a channel of said N-type MOS capacitor.

4. The semiconductor device of claim 2, wherein
said gate electrode of said P-type MOS capacitor is integrated with said gate electrode of said N-type MOS capacitor.

5. The semiconductor device of claim 1, wherein
said P-type MOS capacitor and said N-type MOS capacitor are adjacent; and
there is an element isolation region between said P-type MOS capacitor and said N-type MOS capacitor.

6. The semiconductor device of claim 1, wherein
said decoupling capacitance is placed as a decoupling capacitance cell between standard cells in an element region.

7. The semiconductor device of claim 6, wherein
said decoupling capacitance has a longer gate length than that of said standard cells.

8. The semiconductor device of claim 1, wherein
power supply wiring for said power supply is placed on a N-well region, and ground wiring for said ground is placed on a P-well region.
